(19) United States
(12) Patent Application Publication
(10) Pub. No.: US 2026/0180220 A1
(43) Pub. Date: Jun. 25, 2026

(54) MULTI-AXIS FLOAT CABLE CARTRIDGE ASSEMBLIES

(71) Applicant: Molex, LLC, Lisle, IL (US)

(72) Inventors: Robert Dillman, Santa Clara, CA (US); Jose J. Gonzalez, JR., Joliet, IL (US); John C. Laurx, Aurora, IL (US); Tommy Lawrence, Little Rock, AR (US)

(21) Appl. No.: 19/410,670

(22) Filed: Dec. 5, 2025

Related U.S. Application Data
(60) Provisional application No. 63/736,616, filed on Dec. 20, 2024.

(51) Int. Cl. H01R 12/91; H01R 13/512; H01R 13/516; H01R 13/631

(52) U.S. Cl. CPC H01R 12/91; H01R 13/512; H01R 13/516; H01R 13/631

(57) ABSTRACT

Multi-axis float cable cartridge assemblies and cable cartridge assemblies incorporating floating fasteners are described. An example cable cartridge assembly includes a frame assembly, a mate assurance module including a mate module and connector housings positioned in the mate module, and a floating fastener that secures the mate assurance module with the frame assembly. The mate assurance module can float or move in multiple directions during mating operations with line cards of a line card assembly, to assure a full mating configuration between electrical terminals among the housings in the cable cartridge assembly and the line cards. The floating fastener includes a bias spring, a float bearing ring, and a standoff screw having a head and a shank. The shank extends through a center of the bias spring and through the float bearing ring. The bias spring applies forces against the float bearing ring and the head of the standoff screw.

### BACKGROUND

A range of input/output (I/O) connector panels, bulkheads, backplane assemblies, backplane cable cartridge assemblies, and related cable assemblies are designed for power, data, and power and data interconnects among computing systems in computing environments. A variety of designs exist for each type of system, depending on the requirements of the power and data interconnects needed in the computing environment. As one example, a wire-to-wire connector system includes a first free-end connector attached to one and of a cable bundle and a second free free-end connector attached to one end of another cable bundle. A range of computing, telecommunications, and related systems can rely upon arrays of such wire-to-wire connector system to provide data connectivity between different computing devices, switches, routers, and other equipment. In some cases, the arrays of connector systems are arranged with and secured to backplane cable cartridge assemblies using fasteners, such as screws, bolts, rivets, clips, latches, and other fasteners.

### SUMMARY

Floating connector fasteners and bulkhead assemblies using floating connector fasteners are described. Multi-axis float cable cartridge assemblies and cable cartridge assemblies incorporating floating fasteners are described. An example cable cartridge assembly includes a frame assembly, a mate assurance module including a mate module and connector housings positioned in the mate module, and a floating fastener that secures the mate assurance module with the frame assembly. The cable cartridge assembly can also include a standoff stiffener bar positioned between the frame assembly and the mate assurance module.

The mate assurance module can float or move in multiple directions during mating operations with line cards of a line card assembly, based on the design of the floating fastener, to assure a full mating configuration between electrical terminals among the housings in the cable cartridge assembly and the line cards. An example of the floating fastener includes a bias spring, a float bearing ring, and a standoff screw having a head and a shank. The shank extends through a center of the bias spring and through the float bearing ring. The bias spring applies forces against the float bearing ring and the head of the standoff screw.

In other aspects, the mate assurance module includes the mate module, the plurality of connector housings positioned in the mate module, and a cover plate over the plurality of connector housings. The mate assurance module can include side air ports and a central air port in some cases. The mate assurance module can also include a pair of guide blade structures for gross alignment of the mate assurance module. The mate assurance module can also include a side flange and an aperture through the side flange. The aperture is oversized for a shank of a standoff screw of the floating fastener, to permit movement of the mate assurance module in at least two directions. In other aspects, the mate assurance module includes slots for insertion of positioning rails of the plurality of connector housings into the slots.

Another example of the floating fastener includes a bias spring, a float bearing ring, and a standoff screw. The standoff screw includes a head having a bearing surface and a shank. The shank extends through a center of the bias spring and through the float bearing ring, and the bias spring extends and applies forces against the bearing surface of the standoff screw and against the float bearing ring. When the floating fastener is assembled with the cable cartridge assembly, a threaded region of the shank is secured with the frame, the float bearing ring contacts a surface of a side flange of the mate module, and the bias spring applies forces between the mate module and the frame, to hold the mate assurance module against the frame.

An example mate assurance module includes a mate module, a plurality of connector housings positioned in the mate module, and a cover plate secured to the mate module and over the plurality of connector housings. The mate module can include side air ports and a central air port. The mate module can also include a pair of guide blade structures. The mate module can also include a side flange and an aperture through the side flange. The aperture can be oversized for a shank of a standoff screw of a floating fastener, to permit movement of the mate module in at least two directions. In other aspects, the mate module includes slots for insertion of positioning rails of the plurality of connector housings into the slots.

Another example cable cartridge assembly includes frame assembly, a mate assurance module including a mate module and a plurality of connector housings positioned in the mate module, and a first floating fastener and a second floating fastener. The mate module includes a first side flange with a first aperture through the first side flange and a second side flange with a second aperture through the second side flange. The first aperture is oversized for a first shank of the first floating fastener and the second aperture is oversized for a second shank of the second floating fastener, to permit movement of the mate assurance module in at least two directions.

In other aspects, the mate assurance module can also include a cover plate over the plurality of connector housings. The mate module can also include side air ports and a central air port. The mate module can also include a pair of guide blade structures for gross alignment of the mate assurance module. The mate module can also include slots for insertion of positioning rails of the plurality of connector housings into the slots. Each of the first floating fastener and the second floating fastener can include a bias spring, a float bearing ring, and a standoff screw having a head with a bearing surface and a shank.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1A illustrates a front perspective view of an example cable backplane assembly including a cable cartridge assembly and a mating line card assembly according to various aspects of the present disclosure.

FIG. 1B illustrates a front perspective view of the cable cartridge assembly shown in FIG. 1A, with parts omitted, according to various aspects of the present disclosure.

FIG. 1C illustrates a rear perspective view of parts of the cable cartridge assembly shown in FIG. 1A according to various aspects of the present disclosure.

FIG. 2A illustrates a front perspective view a mate assurance module of the cable cartridge assembly shown in FIG. 1A according to various aspects of the present disclosure.

FIG. 2B illustrates a front view the mate assurance module shown in FIG. 2A according to various aspects of the present disclosure.

FIG. 2C illustrates a top view the mate assurance module shown in FIG. 2A according to various aspects of the present disclosure.

FIG. 2D illustrates a bottom view the mate assurance module shown in FIG. 2A according to various aspects of the present disclosure.

FIG. 2E illustrates a front perspective view of the mate assurance module shown in FIG. 2A, with the connector housings omitted, according to various aspects of the present disclosure.

FIG. 2F illustrates a rear perspective view of the mate assurance module shown in FIG. 2A, with the connector housings omitted, according to various aspects of the present disclosure.

FIG. 3A illustrates a front perspective view of a connector housing in the mate assurance module shown in FIG. 2A according to various aspects of the present disclosure.

FIG. 3B illustrates a back perspective view of the connector housing shown in FIG. 2B, with a wafer assembly, according to various aspects of the present disclosure.

FIG. 4A illustrates a top view of the cable cartridge assembly shown in FIG. 1A, with parts omitted, according to various aspects of the present disclosure.

FIG. 4B illustrates a top view of a mate assurance module of a cable cartridge assembly shown in FIG. 1A according to various aspects of the present disclosure.

FIG. 5A illustrates a perspective view of an example floating connector fastener according to various aspects of the present disclosure.

FIG. 5B illustrates an exploded view of components of the floating connector fastener shown in FIG. 5A according to various aspects of the present disclosure.

FIG. 5C illustrates a sectional view of a bearing ring of the floating connector fastener shown in FIG. 5A according to various aspects of the present disclosure.

FIG. 5D illustrates a sectional view of the floating connector fastener shown in FIG. 5A according to various aspects of the present disclosure.

### DETAILED DESCRIPTION

As noted above, a range of input/output (I/O) connector panels, bulkheads, backplane assemblies, backplane cable cartridge assemblies, and related cable assemblies are designed for power, data, and power and data interconnects among computing systems in computing environments. A variety of designs exist for each type of system, depending on the requirements of the power and data interconnects needed in the computing environment. As one example, a wire-to-wire connector system includes a first free-end connector attached to one end of a cable bundle and a second free free-end connector attached to one end of another cable bundle. A range of computing, telecommunications, and related systems can rely upon arrays of such wire-to-wire connector system to provide data connectivity between different computing devices, switches, routers, and other equipment. In some cases, the arrays of connector systems are arranged with and secured to backplane cable cartridge assemblies using fasteners, such as screws, bolts, rivets, clips, latches, and other fasteners.

A backplane cable cartridge assembly can refer to a structure for organizing and routing cables among connectors that are mounted or otherwise secured to the assembly. A backplane cable cartridge assembly thus supports the connectors and secures them in place with respect to each other and the surrounding assembly and related computing systems. Backplane cable cartridge assemblies can be particularly helpful for wire-to-wire connector systems including many free-end connector housings, which can be arranged and secured together in groups. An example backplane cable cartridge assembly can support a first group of connectors, and a second group of connectors can be mechanically and electrically connected to the first group of the connectors using slot assemblies.

It can be difficult to achieve and maintain precise alignment among the connectors supported on a backplane cable cartridge assembly and the electrical terminals within the connectors. Particularly when connectors are arranged in cable cartridge assemblies, the inter-connector spacings among the connectors in the assemblies, the housings of the connectors, and the electrical terminals within the connectors can fall outside of the specifications for alignment. Cable cartridge assemblies, the connectors supported by the cable cartridge assemblies, and the electrical terminals within the connectors can be damaged in some cases due to such misalignments. At the same time, de-mated or under-mated conditions among the electrical terminals within the connectors can result in reduced and unsuitable signal integrity conditions. Additionally, over-mate conditions among the electrical terminals can result in damage to the terminals and the connectors supported by cable cartridge assemblies, among other undesirable results. Over-mate damage can occur when an individual applies excessive forces between mating connectors or connector assemblies supported by cable cartridge assemblies.

In the context outlined above, the embodiments are directed to multi-axis float cable cartridge assemblies and cable cartridge assemblies incorporating floating fasteners. An example cable cartridge assembly includes a frame assembly, a mate assurance module including a mate module and connector housings positioned in the mate module, and a floating fastener that secures the mate assurance module with the frame assembly. The mate assurance module can float or move in multiple directions during mating operations with line cards of a line card assembly, to assure a full mating configuration between electrical terminals among the housings in the cable cartridge assembly and the line cards. The floating fastener includes a bias spring, a float bearing ring, and a standoff screw having a head and a shank. The shank extends through a center of the bias spring and through the float bearing ring. The bias spring applies forces against the float bearing ring and the head of the standoff screw.

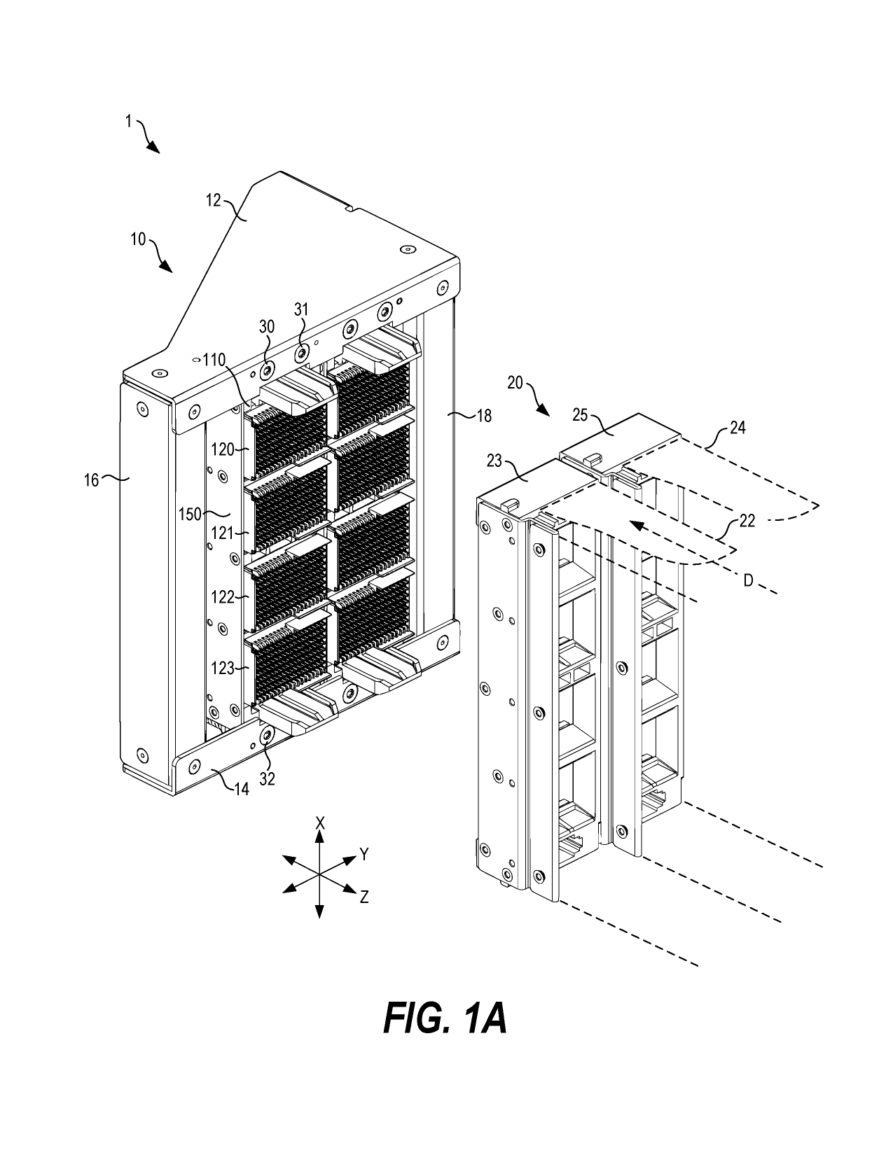

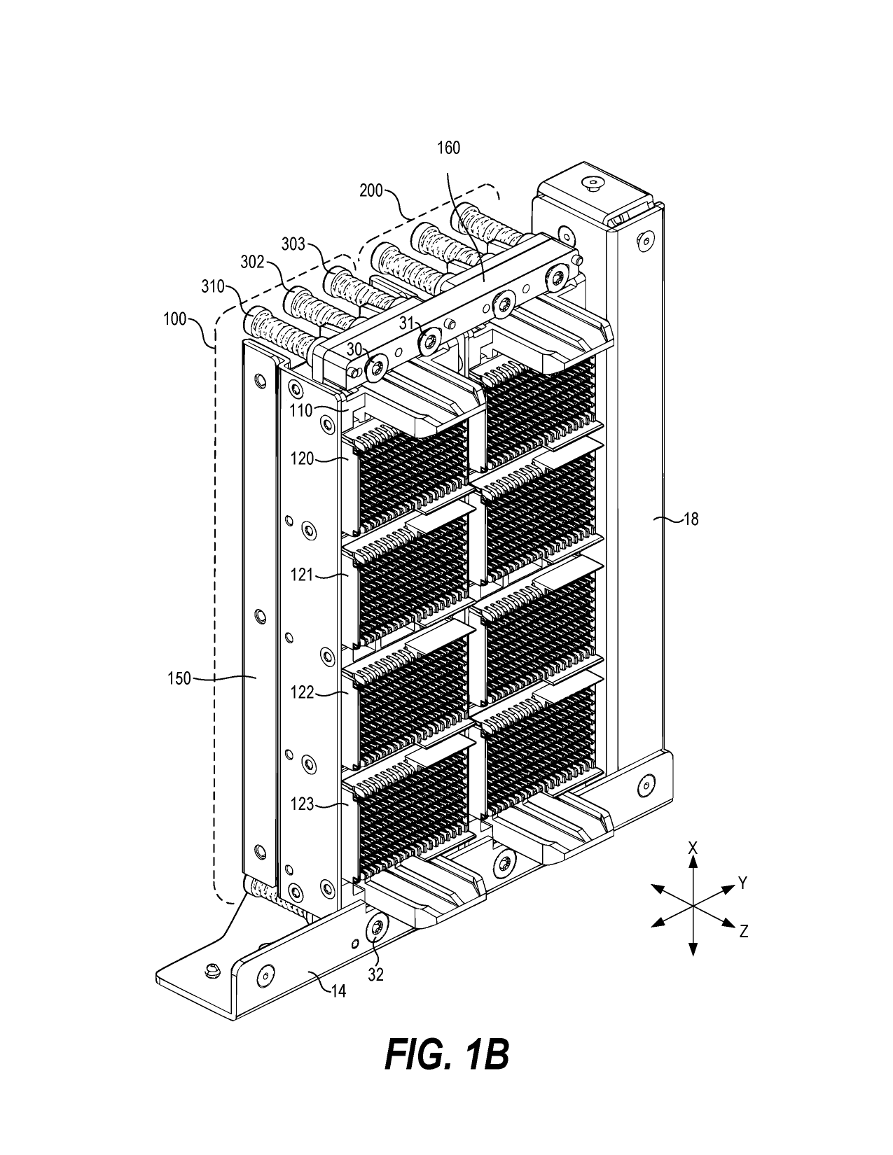

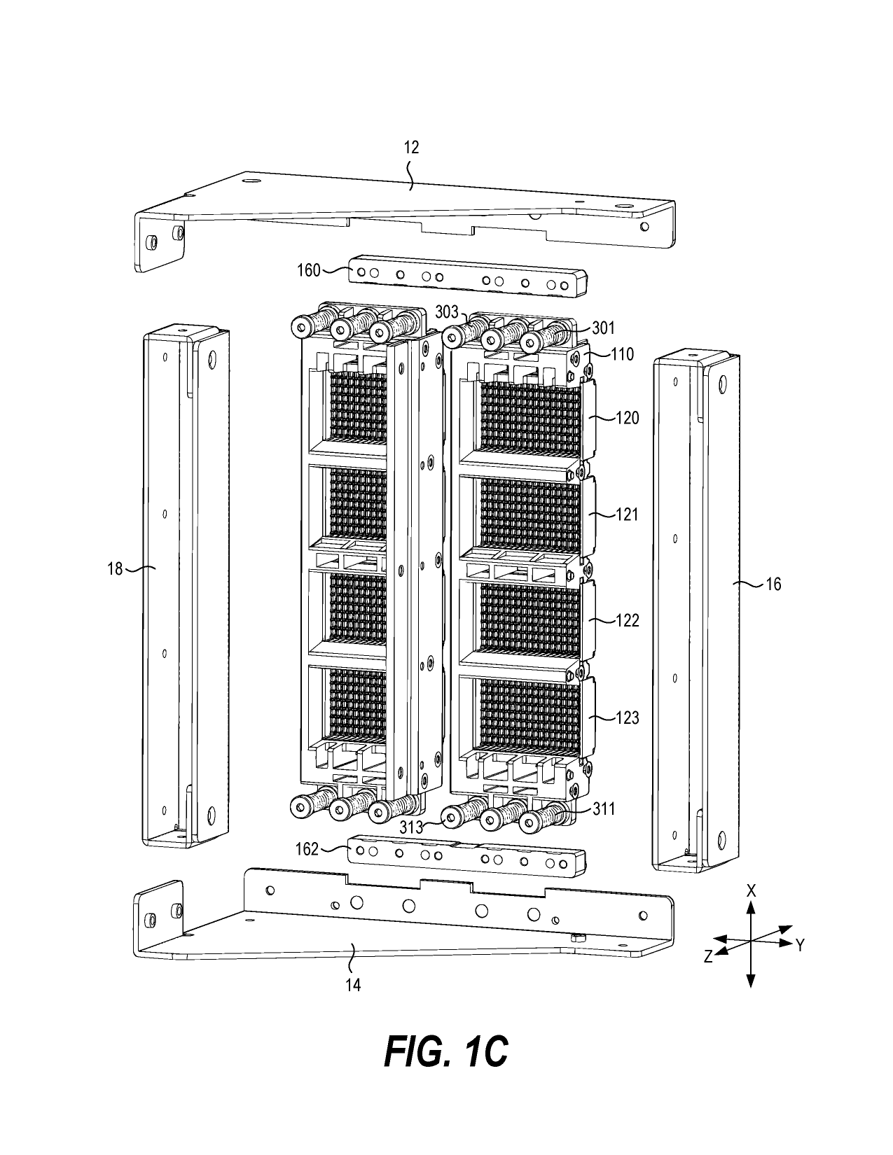

Turning to the drawings, FIG. 1A illustrates a front perspective view of an example cable backplane assembly 1. The cable backplane assembly 1 includes a cable cartridge assembly 10 (also “assembly 10”) and a mating line card assembly 20 in the example shown. The cable backplane assembly 1, cable cartridge assembly 10, and mating line card assembly 20 are illustrated as representative examples and are not drawn to any particular scale or size. The shape, size, proportion, and other characteristics of the cable backplane assembly 1 can vary as compared to that shown. The cable backplane assembly 1 is not exhaustively illustrated, and the cable backplane assembly 1 can include other parts or components that are not illustrated or described in some cases. The cable backplane assembly 1 can also omit one or more of the components illustrated and described in other cases. The cable backplane assembly 1, cable cartridge assembly 10, and mating line card assembly 20 can be used in a range of high speed backplane and related interconnect applications, but the concepts of multi-axis float cable cartridge assemblies are not limited to use with such interconnect applications or systems. The concepts can be extended to use in other types of interconnect applications and systems.

The cable cartridge assembly 10 includes a frame assembly and a number of mate assurance modules. The frame assembly includes a first side bracket 12, a second side bracket 14, a top bracket 16, and a bottom bracket 18. The first side bracket 12, second side bracket 14, top bracket 16, and bottom bracket 18 can be assembled and secured together in the arrangement shown using any suitable fastening means or approaches, such as using screws, bolts, rivets, clips, latches, mechanical interferences, other fasteners, or combinations thereof. The frame assembly can be formed from a range of suitable materials. As examples, the brackets of the frame assembly can be formed from metal, polymer materials (e.g., plastics), fiberglass, resin, composite materials (e.g., combinations of materials) and other suitable materials, including laminated layers in some cases. As a more particular example, the brackets of the frame assembly can be cut and bent, as needed, from a sheet of galvanized steel of between 1-4 mm in thickness, and other metal materials of other thicknesses can be relied upon. The overall size of the frame assembly, including the length (e.g., the “Y” direction shown in FIG. 1A), width (e.g., the “X” direction shown in FIG. 1A), and depth (e.g., the “Z” direction shown in FIG. 1A) of the frame assembly can vary as compared to that shown. For example, the length of the frame assembly can be larger than that shown in FIG. 1A, to accommodate more mate assurance modules, as described below.

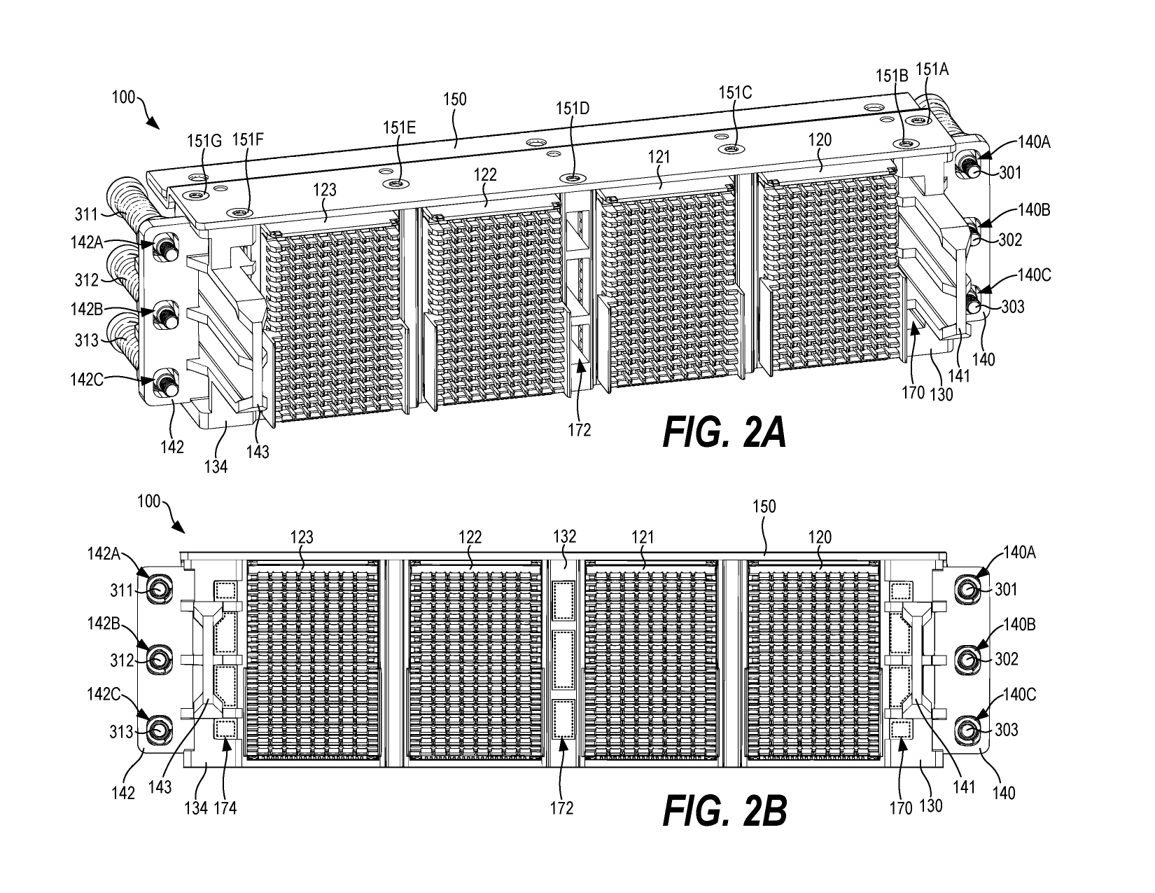

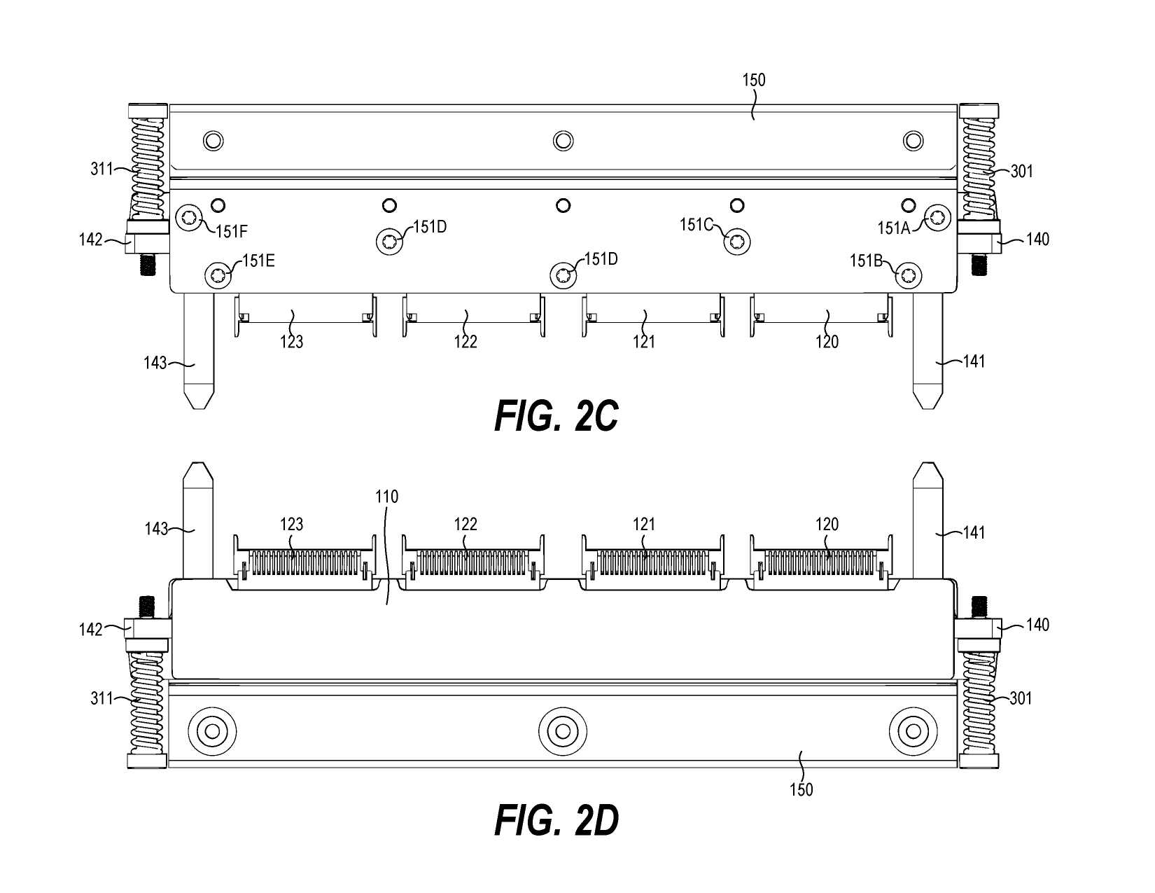

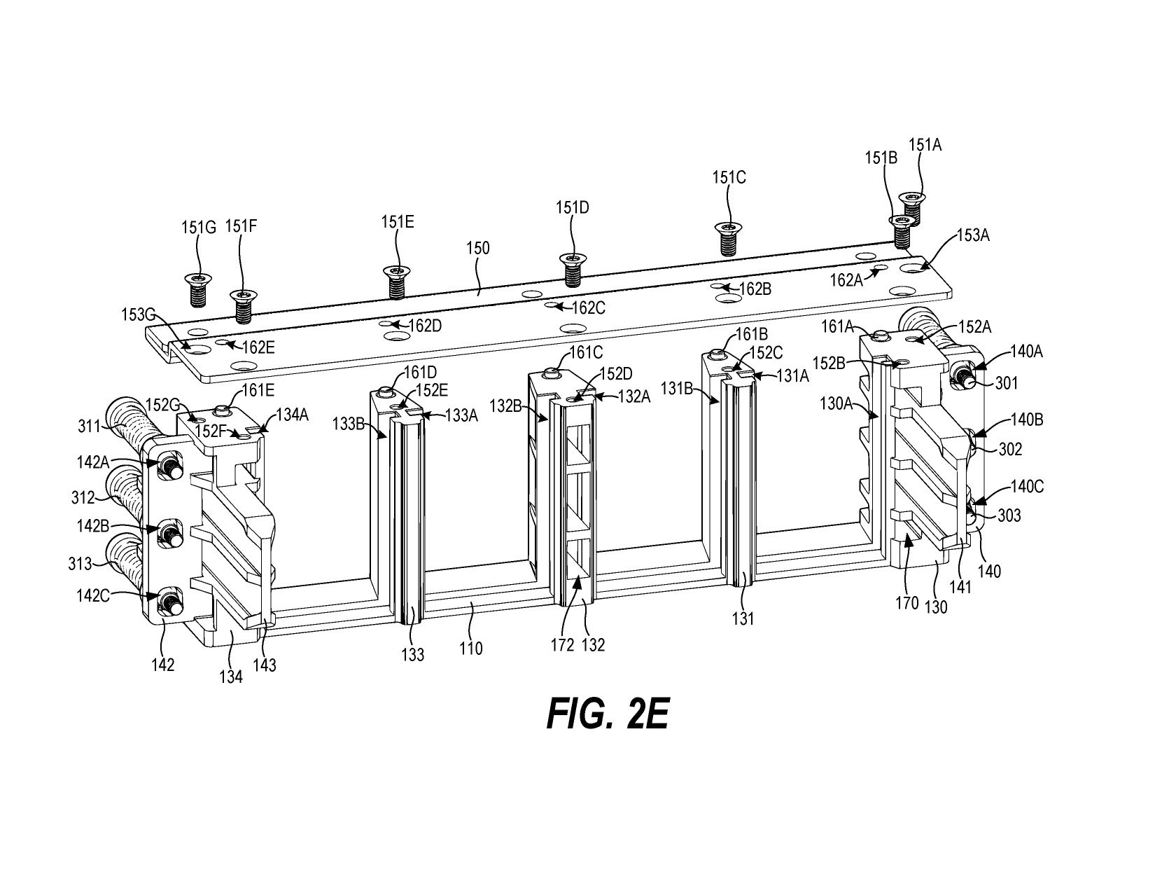

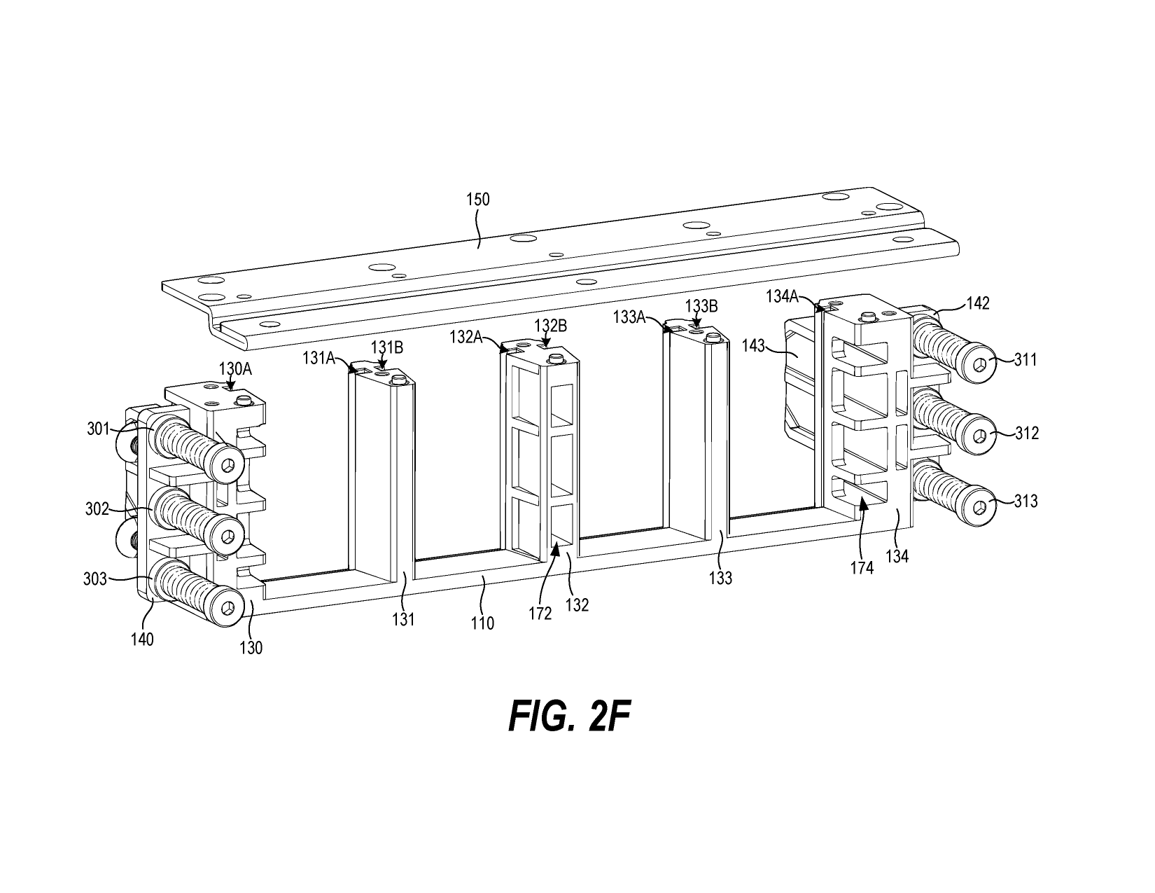

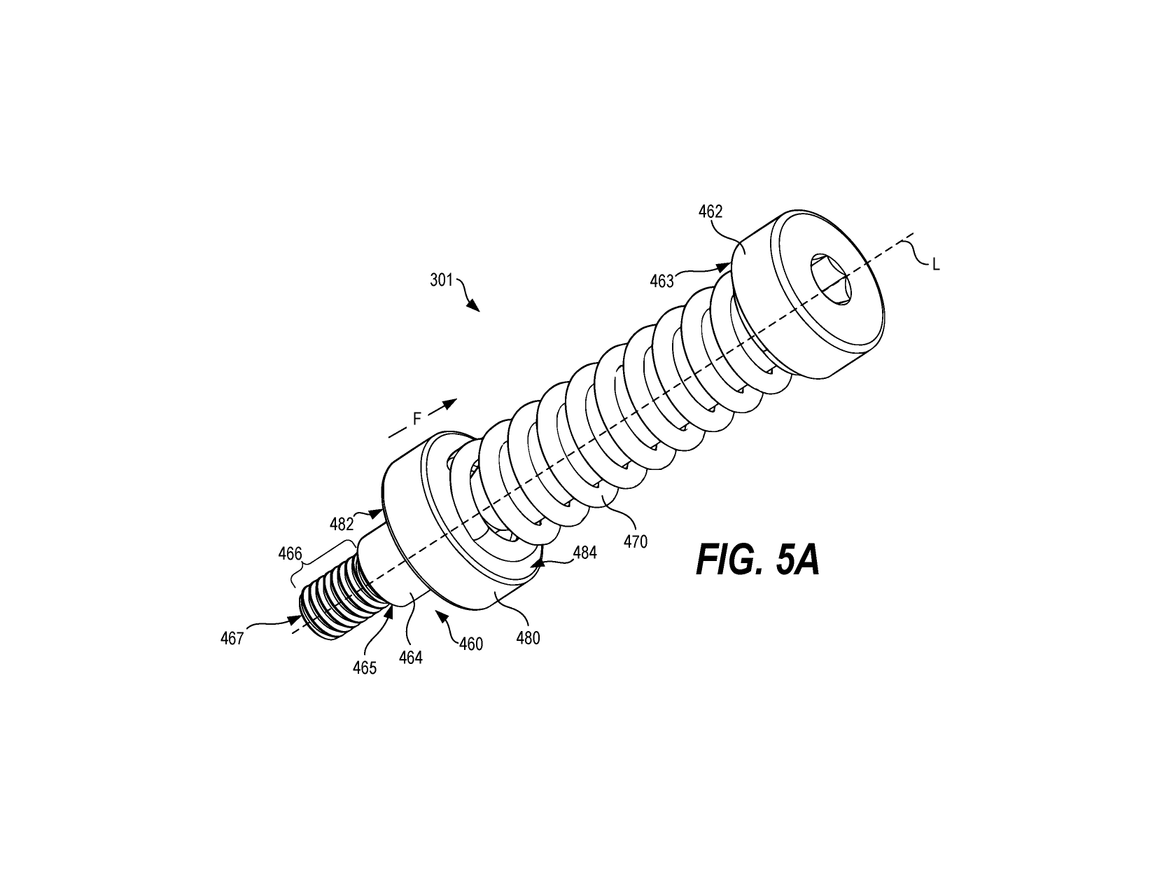

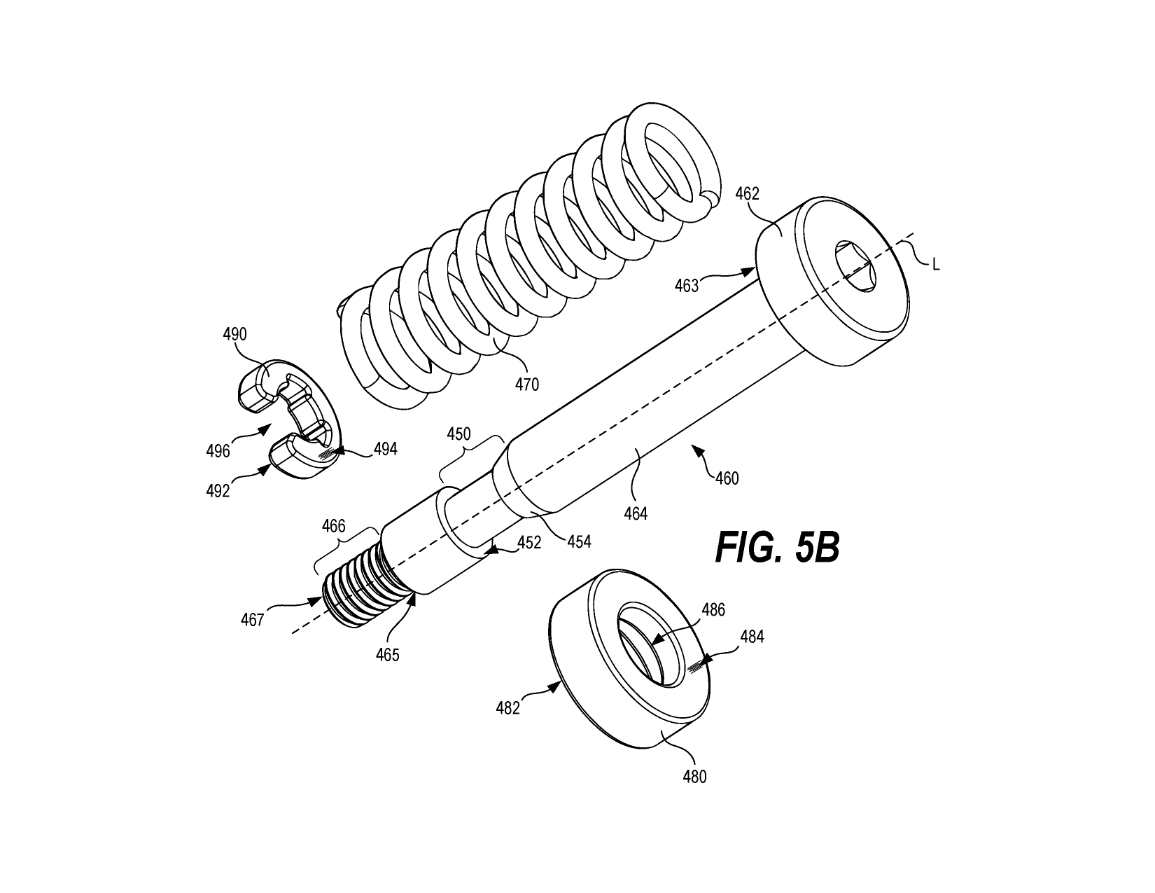

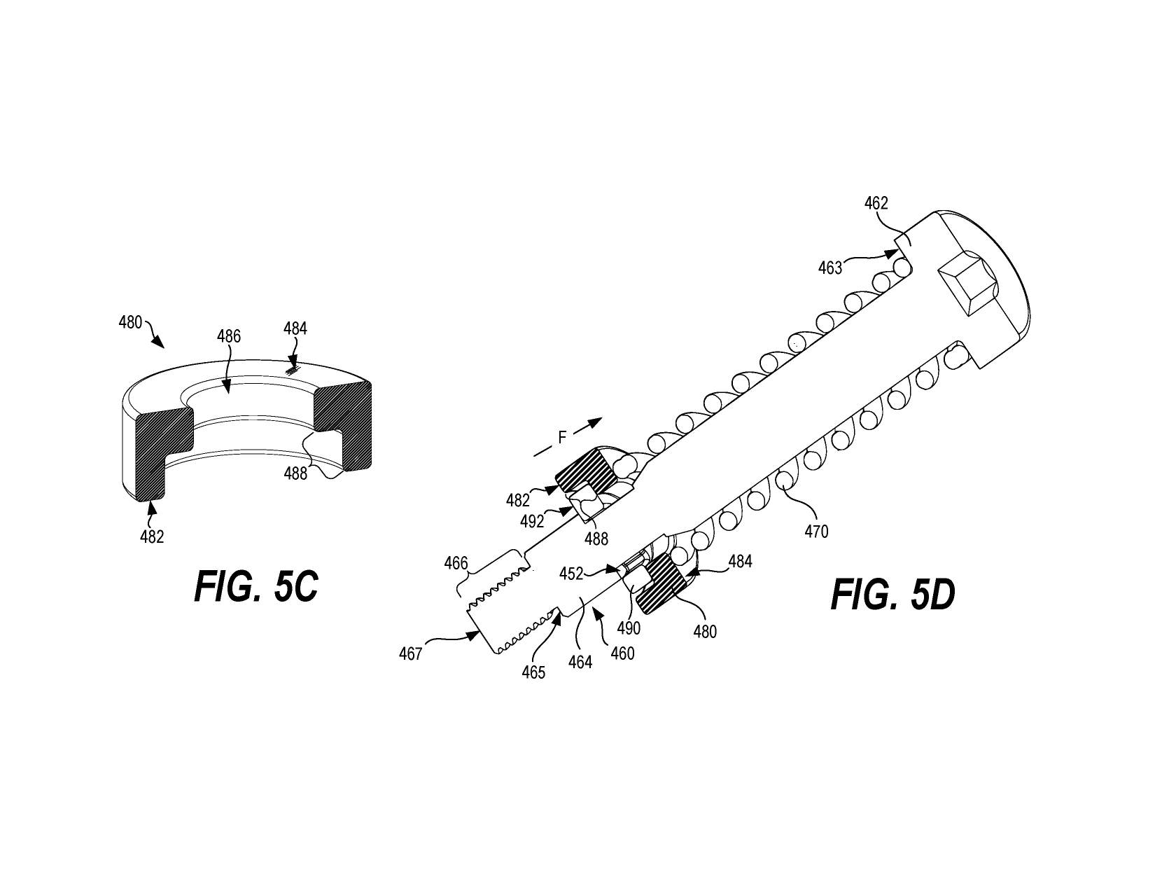

A number of mate assurance modules are secured to and supported by the frame assembly, as described in further detail below. Connector housings are positioned and secured in each of the mate assurance modules. Each of the mate assurance modules, with the connector housings, is secured to and supported by the frame assembly. Detailed views of example mate assurance modules are provided in FIGS. 2A-2D, among others, and the mate assurance modules are described below. A range of different fasteners can be used to secure the mate assurance modules to the frame. According to aspects of the embodiments, the mate assurance modules can be secured to the frame using floating connector fasteners, which are described in further detail below with reference to FIGS. 5A-5D.

The floating connector fasteners are designed to allow some degree of movement between the frame, mate assurance modules, and the connector housings in the mate assurance modules. The cable cartridge assembly 10 thus permits a level of flexibility or play in movement between the frame, the mate assurance modules, and the connector housings in the mate assurance modules. The mate assurance modules can shift or move to some extent in the “X,” “Y,” and “Z” directions shown in FIG. 1A based on the use of the floating connector fasteners. The movement accommodates variations in alignment position, angle, and forces applied between the cable cartridge assembly 10 and line cards 22 and 24, among others, in the mating line card assembly 20. The movement can help to avoid de-mated or under-mated, as well as over-mate conditions, among electrical terminals in the cable cartridge assembly 10 and the line cards 22 and 24. These and other aspects of the embodiments are described below.

FIG. 1B illustrates a front perspective view of the cable cartridge assembly 10 shown in FIG. 1A, with parts omitted. Particularly, the first side bracket 12 and the top bracket 16 are omitted from view in FIG. 1B, so that other components of the cable cartridge assembly 10 can be shown. FIG. 1C illustrates a rear perspective view of parts of the cable cartridge assembly 10 shown in FIG. 1A, with parts of the cable cartridge assembly 10 exploded or expanded apart from each other.

Referring first to FIG. 1B, the cable cartridge assembly 10 includes mate assurance modules 100 and 200 in the example shown. The assembly 10 can include any number of mate assurance modules among various embodiments. As examples, the assembly 10 can include a row of four (4), eight (8), twelve (12), sixteen (16), twenty (20), twenty-four (24), or other numbers of mate assurance modules, and the frame of the assembly 10 can be extended (e.g., in the “Y” direction) to accommodate any number of mate assurance modules. The number of mate assurance modules is also not limited to an even number of mate assurance modules, as the assembly 10 can also include an odd number of mate assurance modules. As one example, the assembly 10 can include twenty-five (25) mate assurance modules. Each of the mate assurance modules can be associated with a slot of the assembly 10.

The mate assurance modules 100 and 200 are illustrated as representative examples and are not drawn to any particular scale or size. The shape, size, proportion, and other characteristics of the mate assurance modules 100 and 200 can vary as compared to that shown. The mate assurance modules 100 and 200 can include additional parts or components in addition to those illustrated and described herein in some cases. The mate assurance modules 100 and 200 can also omit certain parts or components that are described and illustrated in other cases. Detailed views of the mate assurance module 100, as an example of a mate assurance module, are provided in FIGS. 2A-2D and described below. The mate assurance modules 100 and 200 and the connector housings in the mate assurance modules 100 and 200 can be used in a range of high speed cable backplane and related interconnect applications, but the concepts described herein are not limited to use with any particular type or style of interconnect application or system.

The mate assurance module 100 includes a mate module 110, a cover plate 150, and connector housings 100-103, among possibly other components. The mate module 110 can be formed as a single, integral part, using any suitable additive or subtractive manufacturing technique, such as die casting, molding, injection molding, printing, machining, and other techniques. As one example, the mate module 110 can be die cast using zinc or a zinc alloy, although the mate module 110 can also be formed from other materials, including other metals, polymer materials, and other suitable materials. The cover plate 150 can be formed from metal, polymer materials, fiberglass, resin, composite materials, and other suitable materials. As a more particular example, the cover plate 150 can be cut and bent from a sheet of galvanized steel of between 1-4 mm in thickness, and other metal materials of other thicknesses can be relied upon.

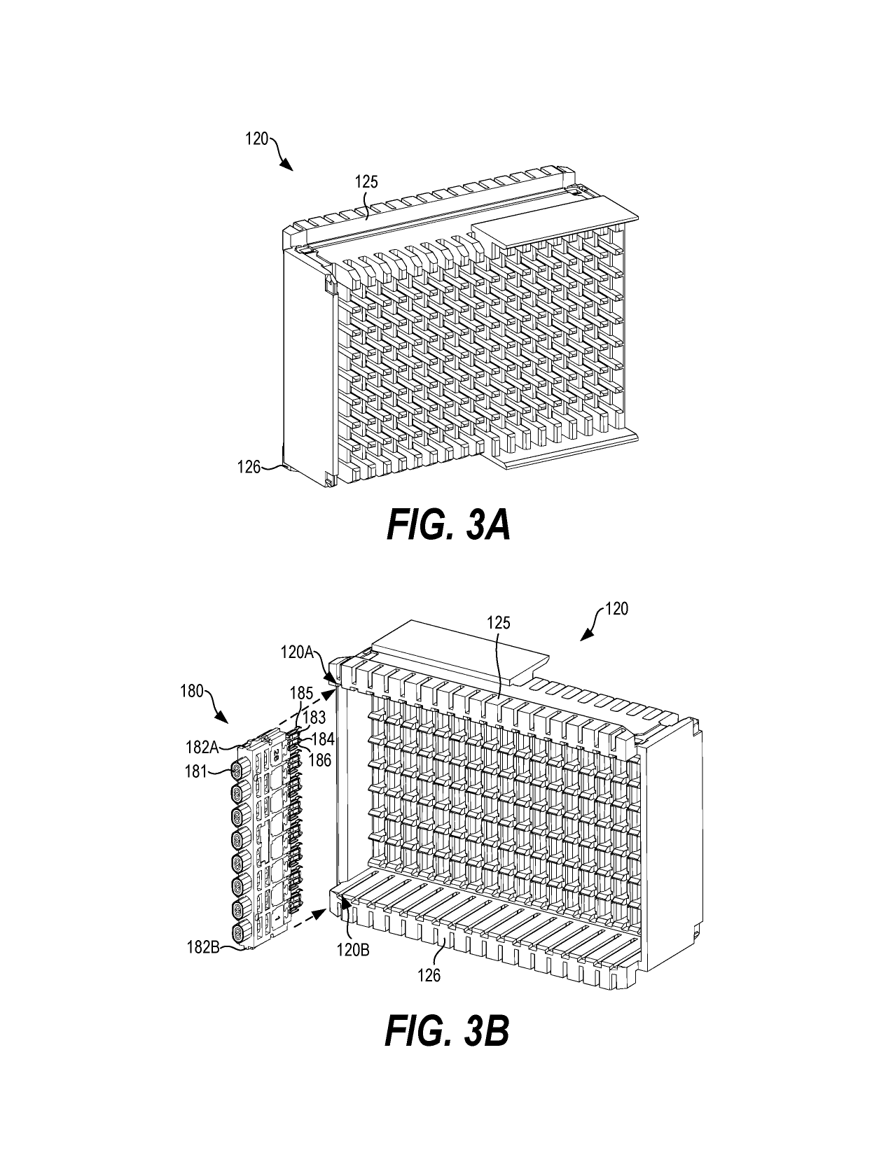

Connector housings 120-123 are positioned in slots of the mate module 110 and secured in place using the cover plate 150, to assemble the mate assurance module 100. An example of the connector housing 120 and wafer assemblies in the connector housing 120 are shown in FIGS. 3A and 3B and described in further detail below. The mate assurance module 100 is secured to the frame of the cable cartridge assembly 10 by a number of floating connector fasteners. The mate assurance module 100 is secured to the first side bracket 12 by floating connector fasteners 301-303 (see FIGS. 1B and 1C) on one side, and the mate assurance module 100 is secured to the second side bracket 14 by floating connector fasteners 301-303 (see FIGS. 1C and 3B) on another side. The mate assurance module 200 is similar to the mate assurance module 100 and can also be secured to the frame of the cable cartridge assembly 10 by a number of floating connector fasteners.

The floating connector fasteners 301-303 secure one side of the mate assurance module 100 to a first standoff stiffener bar 160, and the first standoff stiffener bar 160 is secured to the first side bracket 12 using one or more fasteners, such as screws, bolts, rivets, clips, latches, mechanical interferences, other fasteners, or combinations thereof. In the example shown, the first standoff stiffener bar 160 is secured to the first side bracket 12 using screws 30 and 31 (see FIGS. 1A and 1B), which pass through apertures in the first side bracket 12 and into threaded apertures in the first standoff stiffener bar 160. The floating connector fasteners 311-313 secure another side of the mate assurance module 100 to another standoff stiffener bar 162, and the second standoff stiffener bar 162 is secured to the second side bracket 14 using one or more fasteners, such as screws, bolts, rivets, clips, latches, mechanical interferences, other fasteners, or combinations thereof. In the example shown, the second standoff stiffener bar 162 is secured to the second side bracket 14 using the screw 32 (see FIGS. 1A and 1B), among others, which pass through apertures in the second side bracket 14 and into threaded apertures in the second standoff stiffener bar 162.

The standoff stiffener bars 160 and 162 can be formed from a relatively rigid material, such as steel, although other materials can be relied upon. The standoff stiffener bars 160 and 162 add strength to the cable cartridge assembly 10 and permit the frame to be formed from a reduced amount of lighter weight materials. The standoff stiffener bars 160 and 162 can also be implemented in other ways. For example, both the mate assurance modules 100 and 200 are secured to the frame through the standoff stiffener bars 160 and 162 in the example shown. In other cases, separate or separated standoff stiffener bars can be relied upon to secure the mate assurance modules 100 and 200, individually at each side, to the frame.

The floating connector fasteners 301-303 and 311-313 secure the mate assurance module 100 to the frame of the cable cartridge assembly 10 but also permit an amount of flexibility or play in movement between the frame and the mate assurance module 100. A detailed example of the floating connector fastener 301 is shown in FIGS. 5A-5D and described below. The mate assurance module 100 can shift or move to some extent in the “X,” “Y,” and “Z” directions shown in FIG. 1A based on the use of the floating connector fasteners 301-303 and 311-313. The movement accommodates variations in alignment position, angle, and forces applied between the mate assurance module and the line card 22 in the mating line card assembly 20. The movement can help to avoid de-mated or under-mated, as well as over-mate conditions, among electrical terminals in the cable cartridge assembly 10 and the line cards 22 and 24. Floating connectors can also be helpful in applications where precise dimensional spacing is challenging among connectors, where shocks, over-mate conditions, vibrations, and other factors can be expected, and in other situations.

Each of the connector housings 120-123 includes a number of wafer assemblies and are positioned at the end of a cable bundle, as described below with reference to FIGS. 3A and 3B. Thus, the connector housing 120 is an example of a free-and connector positioned at the end of a cable bundle. Conductors of the wires are electrically coupled to signal and ground terminals of the wafer assemblies within the connector housing 120. The connector housings 120-123 can be hermaphroditic in format. In other words, the connector housing 120 can be rotated and mated with itself.

A housing for the mating line card assembly 20 (not shown) can be secured to the frame of the cable cartridge assembly 10 and include slots for the insertion of the line cards 22 and 24. The line cards 22 and 24 of the mating line card assembly 20 include mating modules 23 and 25, respectively. The line card 22 and mating module 23 of the line card 22 can be inserted (e.g., slid into) into the housing for the mating line card assembly 20 in the direction “D” shown in FIG. 1A, for mating with the mate assurance module 100. Similarly, the line card and 24 and mating module 25 of the line card 24 can be inserted into the housing for the mating line card assembly 20 for mating with the mate assurance module 200.

A number of connector housings (not shown), similar to the connector housings 120-123, can be positioned and secured within the mating module 23 of the line card 22. A cable bundle can extend into the line card 22 and are terminated to wafers (not shown) within the connector housings of the mating module 23. When the line card 22 is sufficiently inserted in the direction “D,” the mating module 23 of the line card 22 can contact and mate with the mate module 110 of the mate assurance module 100. Additionally, the connector housings of the mating module 23 can mate with the connector housings 120-123 of the mate assurance module 100, and the electrical terminals within the connectors can contact and mate with each other. As the surfaces of the mating module 23 of the line card 22, the mate module 110 of the mate assurance module 100, and the connectors and electrical terminals within the connectors contact each other, the mate assurance module 100 can shift or move to some extent in the “X,” “Y,” and “Z” directions shown in FIG. 1A based on the use of the floating connector fasteners 301-303 and 311-313. The movement can help to avoid de-mated or under-mated conditions among the electrical terminals within the connectors can ensure signal integrity across the terminals.

FIG. 2A illustrates a front perspective view the mate assurance module 100 of the cable cartridge assembly 10 shown in FIG. 1A. FIG. 2B illustrates a front view, FIG. 2C illustrates a top view, and FIG. 2D illustrates a bottom view the mate assurance module 100 shown in FIG. 2A. Additionally, FIG. 2E illustrates a front perspective view of the mate assurance module 100 shown in FIG. 2A, with the connector housings 120-123 omitted, and FIG. 2F illustrates a rear perspective view of the mate assurance module 100 with the connector housings 120-123 omitted. The mate assurance module 100 is illustrated as a representative example of a connector housing module that can be used in the cable cartridge assembly 10. The mate assurance module 200 shown in FIG. 1B and described above, and other mate assurance modules of the cable cartridge assembly 10, can be similar to or the same as the mate assurance module 100.

The mate assurance module 100 includes the mate module 110, the connector housings 120-123, and the cover plate 150 among other components. The features of the mate module 110 are best shown in FIGS. 2E and 2F, where the connector housings 120-123 are omitted from view. The mate module 110 includes pillars 130-134, including a first side pillar 130, intermediate pillars 131-133, and a second side pillar 134. The first side pillar 130 includes a first side flange 140, a first guide blade 141, and apertures 140A-140C that extend through the first side flange 140. The floating connector fasteners 301-303 extend through the apertures 140A-140C, as described in further detail below. The second side pillar 134 includes a second side flange 142, a second guide blade 143, and apertures 142A-142C that extend through the second side flange 142. The guide blades 141 and 143 can help with the initial or gross alignment between the mate assurance module 100 and the mating module 23 of the line card 22, which are shown in FIG. 1A, as the line card 22 is inserted in the direction “D” for mating with the mate assurance module 100.

The floating connector fasteners 311-313 extend through the apertures 142A-142C, as described in further detail below. The apertures 140A-140C and 142A-142C are oversized as compared to the size of the standoff screws, and more particularly the shanks of the standoff screws, of the floating connector fasteners 301-303 and 311-313. Thus, a clearance exists between the outer surfaces of the standoff screws in the floating connector fasteners 301-203 and 311-313 and the inner surfaces of the apertures 140A-140C and 142A-142C, which permits the mate assurance module 100 to move in the “X” and “Y” directions shown in FIG. 1A, as also described in further detail below. The sizes of the apertures 140A-140C and 142A-142C can also be smaller or larger than that shown in FIGS. 2B and 2E, to control the range of possible motion or movement of the mate assurance module 100 with respect to the frame of the cable cartridge assembly 10.

One or more of the pillars of the mate module 110 can include air ports or openings for the circulation of air through the mate assurance module 100. In the example shown, the first side pillar 130 includes air ports 170, which are outlined in dashed boxes, the central intermediate pillar 132 includes air ports 172, and the second side pillar 134 includes air ports 174. The intermediate pillars 131 and 133 can also include air ports in some cases, and the air ports can also be omitted from the pillars in other cases. The air ports 170, 172, and 174 permit the circulation of air through the mate assurance module 100 and the cable cartridge assembly 10. The air ports 170 and 174 can be referred to as side air ports, and the air port 172 can be referred to as a central air port in the mate assurance module 100.

The pillars 130-134 also include slots for securing the connector housings 120-123. As best shown in FIGS. 2E and 2F, the first side pillar 130 includes a slot 130A. The pillar 131 includes a slot 131A on one side and a slot 131B on another side. The pillar 132 includes a slot 132A on one side and a slot 132B on another side. The pillar 133 includes a slot 133A on one side and a slot 133B on another side. The second side pillar 134 includes a slot 134A. The connector housings 120-123 are inserted into the slots in the mate module 110. More particularly, the connector housing 120 is inserted into (and between) the slots 130A and 131A between the first side pillar 130 and the intermediate pillar 131. The connector housing 121 is inserted into the slots 131B and 132A between the intermediate pillars 131 and 132. The connector housing 122 is inserted into the slots 132B and 133A between the intermediate pillars 132 and 133. The connector housing 123 is inserted into the slots 133B and 134A between the intermediate pillar 133 and the second side pillar 134. Thus, the connector housings 120-123 are ganged together into the mate module 110 as part of the assembly of the mate assurance module 100.

After the connector housings 120-123 are inserted into the slots in the mate module 110, the cover plate 150 is secured to the mate module 110, to hold the connector housings 120-123 in place. The screw 150A-150G can be used to secure the cover plate 150 to the mate module 110. For example, the screw 151A can be passed through the aperture 153A in the cover plate 150 and threaded into the threaded aperture 152A formed at the top of the first side pillar 130. The screw 151B can also be passed through an aperture in the cover plate 150 and threaded into the threaded aperture 152B formed at the top of the first side pillar 130. The screws 151C-151E can be passed through corresponding apertures in the cover plate 150 and threaded into the threaded apertures 152C-152E formed at the top of the intermediate pillars 131-133, respectively. The screws 151F and 151G can be passed through corresponding apertures in the cover plate 150 and threaded into the threaded apertures 152F and 152G formed at the top of the second side pillar 134. The screws 151A-151G can be embodied as any suitable size and style of screw, including a screw with a torx, star, Phillips, pin, or other type of head with any suitable style of threading (e.g., angle, pitch, and lead thread style).

The locations of the screws 151A-151G and the threaded apertures 152A-152G in the mate module 110 are staggered in position. For example, the threaded apertures 152B, 152D, and 152F can be positioned towards a front of the mate module 110, the threaded apertures 152C and 152E can be positioned in the middle, and the threaded apertures 152A and 152G can be positioned towards a back of the mate module 110. The staggering of the screws 151A-151G and the threaded apertures 152A-152G can provide additional rigidity and strength to the mate assurance module 100. The pillars 130-134 also include locating bosses 161A-161E. When the cover plate 150 is positioned on the mate module 110, the locating bosses 161A-161E fit into locating apertures 162A-162E of the cover plate 150, to help hold the cover plate 150 in place and provide additional rigidity and strength to the mate assurance module 100.

FIG. 3A illustrates a front perspective view of the connector housing 120 in the mate assurance module 100 shown in FIG. 2A, and FIG. 3B illustrates a back perspective view of the connector housing 120 shown in FIG. 2B, with a wafer assembly 180 for insertion into the connector housing 120. The connector housing 120 can be formed from a plastic or polymer, such as liquid crystal polymer (LCP), polyethylene (PE), polytetrafluoroethylene (PTFE), fluoropolymer, or other plastic or insulating material(s). The connector housing 120 can be formed using any suitable additive or subtractive manufacturing techniques, including molding, injection molding, printing, and other techniques. Each of the connector housings 121-123 in the mate assurance module 100 can be the same or substantially the same as the connector housing 120, although the connector housings 120-123 can vary as compared to each other in some cases.

Outer surfaces of the connector housing 120 can be selectively metalized or plated with a plating metal or metals for conductivity in some embodiments, and the connector housing 120 can be embodied as a plated plastic component. In one embodiment, the entirety of all exterior-facing outer surfaces of the connector housing 120 can be plated with a metal or metals for conductivity. In other cases, only certain interior and/or exterior surfaces or surface regions of the connector housing 120 can be plated. The plating facilitates the use of the connector housing 120 as a type of electromagnetic interference (EMI) shield. The connector housing 120 can also be formed from a conductive material other than a plastic or polymer in other cases. The connector housing 120 can also be formed from aluminum, copper, brass, or another metal or metal alloy as an alternative to plastic. The connector housing 120 can be self-conductive in that case without surface plating.

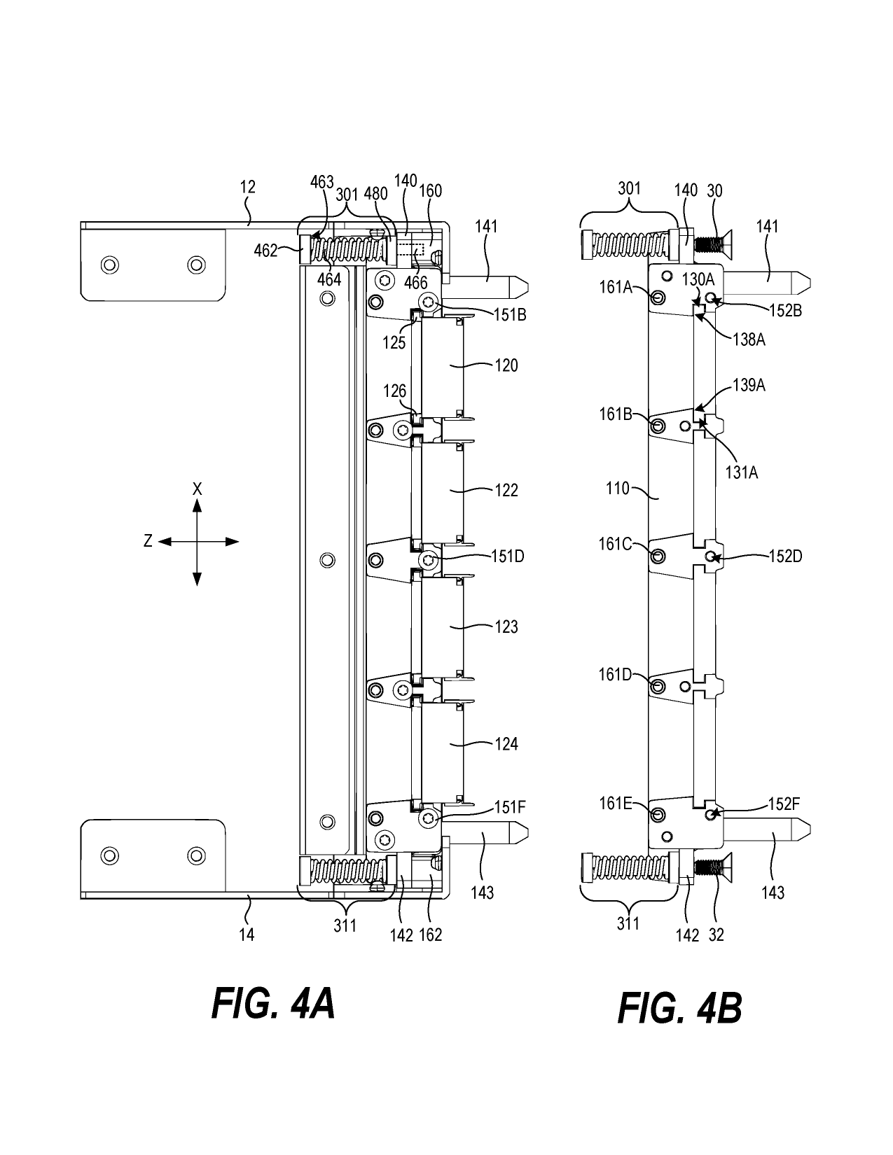

The connector housing 120 includes positioning rails 125 and 126 in the example shown. The positioning rails 125 and 126 can slide into the slots 130A and 131A between the first side pillar 130 and the intermediate pillar 131 of the mate module 110, as shown in FIGS. 2E and 4B, when the mate assurance module 100 is assembled. The connector housing 120 also includes an open region and a number of slots formed in the back side of the connector housing 120, as shown in FIG. 3B. The slots 120A and 120B are separately referenced in FIG. 3B as examples, and a wafer assembly can be inserted into the slots 120A and 120B, as described below.

The wafer assembly 180, as one example among others, can be positioned in the connector housing 120. The connector housing 120 can be designed to accommodate eighteen (18) wafers in the example shown, although the connector housing 120 can be designed to accommodate a different number of wafers in other cases. A number of cables, such as the cable 181, extend to and are terminated at the wafer assembly 180. Eight (8) cables extend to and are terminated at the wafer assembly 180 in the example shown, and other types and styles of wafers with a different number of cables can be relied upon in other cases. The cable 181 can be embodied as a twinaxial or twinax cable including a pair of signal conductors insulated by a central dielectric insulating material and one or more drain or ground conductors, suitable for high-speed differential data signaling applications. The signal conductors of the cable 181 can be terminated to signal terminals 183 and 184 of the wafer assembly 180. The drain conductors of the cable 181 can be terminated to ground terminals 185 and 186 of the wafer assembly 180. The other cables terminated at the wafer assembly 180 can be terminated to other signal and ground terminals of the wafer assembly 180.

The wafer assembly 180 includes side rails 182A and 182B, which extend along peripheral side edges of the wafer assembly 180. The wafer assembly 180 can be inserted into the connector housing 120, with the side rails 182A and 182B being positioned into the slots 120A and 120B of the connector housing 120, respectively. Other wafer assemblies can be inserted into other slots of the connector housing 120, and the connector housing 120 is an example of a free-end connector at the end of a cable bundle.

FIG. 4A illustrates a top view of the cable cartridge assembly 10 shown in FIG. 1A, with the top bracket 16 and the cover plate 150 omitted from view. FIG. 4B illustrates a top view of the mate assurance module 100 shown in FIG. 1A with the cover plate 150 and the connector housings 120-123 omitted from view. After the wafer assembly 180, among others, have been inserted into the connector housing 120 as described above with reference to FIG. 3B, the positioning rails 125 and 126 of the connector housing 120 can be inserted into the slots 130A and 131A between the first side pillar 130 and the intermediate pillar 131 of the mate module 110, as shown in FIG. 4A. The other connector housings 121-123 can be assembled with other wafers in a similar way and inserted into the mate module 110. The cover plate 150 can then be secured to the mate module 110 to hold the connector housings 120-123 in place.

With the connector housing 120 positioned in the mate module 110, the positioning rails 125 and 126 of the connector housing 120 mechanically interfere with the inner surfaces of the slots 130A and 131A of the mate module 110, as best shown in FIG. 4A, preventing the connector housing 120 from being removed from the mate module 110. Additionally, the side rails 182A and 182B of the wafer assembly 180 (see FIG. 3B) mechanically interfere with back surfaces 138A and 139A of the slots 130A and 131A of the mate module 110, as best shown in FIG. 4B, preventing the wafer assembly 180 from being removed from the connector housing 120. The other wafer assemblies in the connector housing 120 are secured in a similar way.

As shown in FIG. 4A, the floating connector fasteners 301-303 (see also FIGS. 2A and 2B) secure one side of the mate assurance module 100 to the first standoff stiffener bar 160, and the first standoff stiffener bar 160 is secured to the first side bracket 12. In the example shown, the first standoff stiffener bar 160 is secured to the first side bracket 12 using screws 30 and 31 (see also FIGS. 1A and 1B), which pass through apertures in the first side bracket 12 and into threaded apertures in the first standoff stiffener bar 160. The floating connector fasteners 311-313 (see also FIGS. 2A and 2B) secure another side of the mate assurance module 100 to the second standoff stiffener bar 162, and the second standoff stiffener bar 162 is secured to the second side bracket 14 using the screw 32 (see FIGS. 1A and 1B), among others, which pass through apertures in the second side bracket 14 and into threaded apertures in the second standoff stiffener bar 162.

The floating connector fasteners 301-303 and 311-313 thus secure the mate assurance module 100 to the frame of the cable cartridge assembly 10 but also permit an amount of flexibility or play in movement between the frame and the mate assurance module 100. A detailed example of the floating connector fastener 301 is shown in FIGS. 5A-5D and described below. The mate assurance module 100 can shift or move to some extent in the “X,” “Y,” and “Z” directions shown in FIG. 1A based on the use of the floating connector fasteners 301-303 and 311-313. The movement accommodates variations in alignment position, angle, and forces applied between the mate assurance module and the line card 22 in the mating line card assembly 20, as shown in FIG. 1A and described above. The movement can help to avoid de-mated or under-mated, as well as over-mate conditions, among electrical terminals in the cable cartridge assembly 10 and the line card 22. Floating connectors can also be helpful in applications where precise dimensional spacing is challenging among connectors, where shocks, over-mate conditions, vibrations, and other factors can be expected, and in other situations.

FIG. 5A illustrates a perspective view of the floating connector fastener 301 (also “floating fastener 301”) according to various aspects of the present disclosure. FIG. 5B illustrates an exploded view of components of the floating fastener 301. The floating fastener 301 is a floating connector fastener as described herein. Each of the floating connector fasteners 302, 303, and 311-313 can be the same or substantially the same as the floating fastener 301. The floating fastener 301 is illustrated as a representative example and is not drawn to any particular scale or size. The shape, size, proportion, and other characteristics of the floating fastener 301 can vary as compared to that shown in other embodiments.

Referring between FIGS. 5A and 5B, the floating fastener 301 includes a standoff screw 460, a bias spring 470, a float bearing ring 480, and a locking clip 490. The standoff screw 460 can be embodied as any suitable size and style of screw, including a screw with a torx, star, Phillips, pin, or other type of head with any suitable style of threading (e.g., angle, pitch, and lead thread style). The standoff screw 460 includes a head 462, a shank 464, a threaded region 466, and a tip 467 at an end of the shank 464. The head 462 is formed as a recessed flat torx head in the example shown, although other types of heads can be relied upon. The threaded region 466 extends for a shorter distance along the longitudinal axis “L” of the standoff screw 460 than the shank 464. The threaded region 466 of the standoff screw 460 can be threaded into a threaded aperture in one of the stiffener bar 160, for example, until the shaft bearing surface 465 contacts an exterior surface of the stiffener bar 160, which prevents the standoff screw 460 from being threaded any further into the stiffener bar 160.

As shown in FIG. 5B, the shank 464 of the standoff screw 460 includes a bearing slide region 450 that extends a distance along the longitudinal axis “L” of the shank 464. The size or length of the bearing slide region 450 is shown as an example in FIG. 5B and can vary as compared to that shown. The bearing slide region 450 is a length of the shank 464 that has a reduced outer surface circumference as compared to remaining portion of the shank 464. The bearing slide region 450 includes a locking rim 452 at one end and a taper ring 454 at another end. The locking rim 452 includes an annular ring surface extending in a plane that is substantially perpendicular to the longitudinal axis “L” of the shank 464. The taper ring 454 is a conical region that tapers from the reduced circumference of the bearing slide region 450, which is closer to the tip 467, to the increased circumference of the remaining shank 464, which is closer to the head 462. The function and purpose of the bearing slide region 450 is described in further detail below.

The bias spring 470 can be embodied as a spring formed from high-carbon spring steel, alloy spring steel, stainless spring steel, copper-based spring alloys, nickel-based spring alloys, or other suitable materials. The bias spring 470 can be selected or manufactured to have a suitable spring constant, k, for holding or biasing the mate assurance module 100 against the first side bracket 12 of the frame, for example. The spring constant, k, can also be selected for absorbing the forces applied to the mate assurance module 100 during over-mate conditions. The bias spring 470 can be formed to any suitable length, include any number of turns, and is sized so that the shank 464 of the standoff screw 460 can extend through the center of the bias spring 470 with a clearance between them.

The float bearing ring 480 can be embodied as a ring formed of metal, polymer materials, or other suitable materials. The float bearing ring 480 includes a ring bearing surface 482 and a spring bearing surface 484, both of which are annular, flat, and extend in separate and substantially parallel planes. A central aperture 486 extends through the float bearing ring 480 and the surfaces 482 and 484. The locking clip 490 can be embodied as a C-shaped clip formed of metal, polymer materials, or other suitable materials. The locking clip 490 includes a lock bearing surface 492 and a float bearing surface 494. The lock bearing surface 492 and float bearing surface 494 are both flat and extend in separate and substantially parallel planes.

To assemble the fastener 400, the tip 467 of the standoff screw 460 can be inserted through the center of the bias spring 470 so that the bias spring 470 is coiled around the shank 464 and positioned against the head 462 of the standoff screw 460 as shown in FIG. 5A. The tip 467 of the standoff screw 460 can also be inserted through the central aperture 486 of the float bearing ring 480. The float bearing ring 480 can be pushed against and contacted with the end of the bias spring 470. A force in the direction “F” shown in FIG. 5A can then be applied to the float bearing ring 480 to compress the bias spring 470 and reveal the bearing slide region 450. The locking clip 490 can then be snapped into and onto the bearing slide region 450 of the shank 464, and the float bearing ring 480 can be released. The float bearing ring 480 will then be biased to seat against the locking clip 490 by the extension of the bias spring 470.

FIG. 5C illustrates a sectional view of the float bearing ring 480 of the floating fastener 301. As shown in FIG. 7C, the float bearing ring 480 includes an annular recess 488. The size of the annular recess 488 is sufficient to encompass (i.e., extend around or extend over) the locking clip 490. In other words, the inner circumferential surface within the annular recess 488 is larger than the outer circumferential surface of the locking clip 490, with a clearance between them.

FIG. 5D illustrates a sectional view of the floating fastener 301. As shown, the bias spring 470 is coiled around the shank 464. In the configuration shown in FIG. 5D, the bias spring 470 applies spring forces against the bearing surface 463 of the standoff screw, at one end, and against the spring bearing surface 484 of the float bearing ring 480, at another end. The shank 464 of the standoff screw 460 extends through the central aperture of the float bearing ring 480. The float bearing ring 480 is seated upon the locking clip 490, with the locking clip 490 positioned within the annular recess 488 of the float bearing ring 480. The locking clip 490 contacts and is seated upon the locking rim 452 of the bearing slide region 450 (see FIG. 5B). Thus, the locking clip 490 provides a mechanical interference that prevents the bias spring 470 from pushing the float bearing ring 480 any further towards the tip 467 of the standoff screw 460.

The float bearing ring 480 can slide along the bearing slide region 450 (see FIG. 5B) and along the shank 464 of the standoff screw 460, toward the head 462 of the standoff screw 460, based on application of a force in the direction “F” shown in FIG. 5A. That is, to the extent that the force in the direction “F” overcomes the spring bias provided by the bias spring 470, the float bearing ring 480 can slide along the bearing slide region 450 and the shank 464 of the standoff screw 460. The locking clip 490, on the other hand, can slide along the bearing slide region 450 but cannot slide along the shank 464 of the standoff screw 460. Instead, the taper ring 454 (see FIG. 5B) prevents the locking clip 490 from sliding past or beyond the bearing slide region 450.

When used with the mate assurance module 100, the shank 464 of the floating fastener 301 extends through the aperture 140A in the first side flange 140 of the mate module 110, as shown in FIGS. 2A and 2B. The threaded region 466 of the shank 464 is threaded into a threaded aperture of the stiffener bar 160, and the float bearing ring 480 rests upon a back surface of the first side flange 140 of the mate module 110, as shown with reference to FIG. 4A. In that arrangement, the float bearing ring 480 applies a force and pushes against the back surface of the first side flange 140. At the same time, the threaded region 466 of the shank 464 pulls and applies an opposing force on the stiffener bar 160, holding the first side flange 140 against the stiffener bar 160. The opposing forces are applied based on the spring bias provided by the bias spring 470, which acts between and against the bearing surface 463 of the standoff screw 460 and the float bearing ring 480. The spring bias can be overcome, however, depending on the extent of the forces applied to the connector housings 120-123, for example, in the mate assurance module 100.

The stiffener bars 160 and 162 can also be omitted in other examples. In that case, the threaded region 466 of the shank 464 can be threaded into a threaded aperture of the first side bracket 12, and the float bearing ring 480 can rest upon a back surface of the first side flange 140 of the mate module 110. In that arrangement, the float bearing ring 480 applies a force and pushes against the back surface of the first side flange 140. At the same time, the threaded region 466 of the shank 464 pulls and applies an opposing force on the first side bracket 12, holding the first side flange 140 against the first side bracket 12. The opposing forces are applied based on the spring bias provided by the bias spring 470, which acts between and against the bearing surface 463 of the standoff screw 460 and the float bearing ring 480.

Overall, the floating connector fasteners 301-303 and 311-313 are designed to secure the mate assurance module 100 to the stiffener bars 160 and 162 and/or to the frame of the cable cartridge assembly 10. The floating connector fasteners 301-303 and 311-313 are also designed to absorb forces associated with mating and over-mate conditions. Thus, forces associated with over-mate conditions, such as a force in the direction “F” shown in FIG. 5A, will counteract against and overcome the spring bias provided by the floating connector fasteners 301-303 and 311-313. The floating connector fasteners 301-303 and 311-313 are designed to facilitate manufacturing tolerances and the accommodation of variations in alignments, positions, angles, or forces among the mate assurance module 100 and the line card 22, as shown in FIG. 1A. Depending on the direction of the forces applied, the floating connector fasteners 301-303 and 311-313 can also permit the mate assurance module 100 to tilt or twist to some extent.

Terms such as “top,” “bottom,” “side,” “front,” “back,” “right,” and “left” are not intended to provide an absolute frame of reference. Rather, the terms are relative and are intended to identify certain features in relation to each other, as the orientation of structures described herein can vary. The terms “comprising,” “including,” “having,” and the like are synonymous, are used in an open-ended fashion, and do not exclude additional elements, features, acts, operations, and so forth. Also, the term “or” is used in its inclusive sense, and not in its exclusive sense, so that when used, for example, to connect a list of elements, the term “or” means one, some, or all of the elements in the list.

Combinatorial language, such as “at least one of X, Y, and Z” or “at least one of X, Y, or Z,” unless indicated otherwise, is used in general to identify one, a combination of any two, or all three (or more if a larger group is identified) thereof, such as X and only X, Y and only Y, and Z and only Z, the combinations of X and Y, X and Z, and Y and Z, and all of X, Y, and Z. Such combinatorial language is not generally intended to, and unless specified does not, identify or require at least one of X, at least one of Y, and at least one of Z to be included. The terms “about” and “substantially,” unless otherwise defined herein to be associated with a particular range, percentage, or related metric of deviation, account for at least some manufacturing tolerances between a theoretical design and manufactured product or assembly, such as the geometric dimensioning and tolerancing criteria described in the American Society of Mechanical Engineers (ASME®) Y14.5 and the related International Organization for Standardization (ISO®) standards. Such manufacturing tolerances are still contemplated, as one of ordinary skill in the art would appreciate, although “about,” “substantially,” or related terms are not expressly referenced, even in connection with the use of theoretical terms, such as the geometric “perpendicular,” “orthogonal,” “vertex,” “collinear,” “coplanar,” and other terms.

The above-described embodiments of the present disclosure are merely examples of implementations to provide a clear understanding of the principles of the present disclosure. Many variations and modifications can be made to the above-described embodiments without departing substantially from the spirit and principles of the disclosure. In addition, components and features described with respect to one embodiment can be included in another embodiment. All such modifications and variations are intended to be included herein within the scope of this disclosure.

What is claimed is:

1. A cable cartridge assembly, comprising:
frame assembly;
a mate assurance module comprising a mate module and a plurality of connector housings positioned in the mate module; and
a floating fastener that secures the mate assurance module with the frame assembly.

2. The cable cartridge assembly according to claim 1, wherein the mate assurance module comprises the mate module, the plurality of connector housings positioned in the mate module, and a cover plate over the plurality of connector housings.

3. The cable cartridge assembly according to claim 1, wherein the mate assurance module comprises side air ports and a central air port.

4. The cable cartridge assembly according to claim 1, wherein the mate assurance module comprises a pair of guide blade structures for gross alignment of the mate assurance module.

5. The cable cartridge assembly according to claim 1, wherein the mate assurance module comprises a side flange and an aperture through the side flange, and the aperture is oversized for a shank of a standoff screw of the floating fastener, to permit movement of the mate assurance module in at least two directions.

6. The cable cartridge assembly according to claim 1, wherein the mate assurance module comprises slots for insertion of positioning rails of the plurality of connector housings into the slots.

7. The cable cartridge assembly according to claim 1, further comprising a standoff stiffener bar positioned between the frame assembly and the mate assurance module.

8. The cable cartridge assembly according to claim 1, wherein the floating fastener comprises:
a bias spring;
a float bearing ring; and
a standoff screw comprising a head with a bearing surface and a shank, wherein:
the shank extends through a center of the bias spring and through the float bearing ring, and
the bias spring extends and applies forces against the bearing surface of the standoff screw and against the float bearing ring.

9. The cable cartridge assembly according to claim 8, wherein:
a threaded region of the shank is secured with the frame,
the float bearing ring contacts a surface of a side flange of the mate module, and the bias spring applies forces between the mate module and the frame, to hold the mate assurance module against the frame.

10. A mate assurance module, comprising:
a mate module;
a plurality of connector housings positioned in the mate module; and
a cover plate secured to the mate module and over the plurality of connector housings.

11. The mate assurance module according to claim 10, wherein the mate module comprises side air ports and a central air port.

12. The mate assurance module according to claim 10, wherein the mate module comprises a pair of guide blade structures.

13. The mate assurance module according to claim 10, wherein the mate module comprises a side flange and an aperture through the side flange, and the aperture is oversized for a shank of a standoff screw of a floating fastener, to permit movement of the mate module in at least two directions.

14. The mate assurance module according to claim 1, wherein the mate module comprises slots for insertion of positioning rails of the plurality of connector housings into the slots.

15. A cable cartridge assembly, comprising:
frame assembly;
a mate assurance module comprising a mate module and a plurality of connector housings positioned in the mate module, the mate module comprising a first side flange with a first aperture through the first side flange and a second side flange with a second aperture through the second side flange; and
a first floating fastener and a second floating fastener, wherein the first aperture is oversized for a first shank of the first floating fastener and the second aperture is oversized for a second shank of the second floating fastener, to permit movement of the mate assurance module in at least two directions.

16. The cable cartridge assembly according to claim 15, wherein the mate assurance module further comprises a cover plate over the plurality of connector housings.

17. The cable cartridge assembly according to claim 15, wherein the mate module comprises side air ports and a central air port.

18. The cable cartridge assembly according to claim 15, wherein the mate module comprises a pair of guide blade structures for gross alignment of the mate assurance module.

19. The cable cartridge assembly according to claim 15, wherein the mate module comprises slots for insertion of positioning rails of the plurality of connector housings into the slots.

20. The cable cartridge assembly according to claim 15, wherein the first floating fastener comprises:
a bias spring;
a float bearing ring; and
a standoff screw comprising a head with a bearing surface and a shank.
